(19) United States
(12) Patent Application Publication
(10) Pub. No.: US 2009/0179662 A1
(43) Pub. Date: Jul. 16, 2009

(54) System for Monitoring Individual Photovoltaic Modules

(76) Inventors: Thomas A. Moulton, New Port Richey, FL (US); Eric Wilhelmson, New Port Richey, FL (US)

Correspondence Address: GREENBERG & LIEBERMAN, LLC, 2141 WISCONSIN AVE, N.W., SUITE C-2, WASHINGTON, DC, 20007, US

(21) Appl. No.: 11/972,222

(22) Filed: Jan. 10, 2008

(51) Int. Cl. G01R 31/40

(52) U.S. Cl. 324/771

(57) ABSTRACT

A system for monitoring the power output levels for each photovoltaic module of a solar array. The system connects individual photovoltaic module with its own voltage level sensing circuit, where the power output data is transferred through wired and wireless means to be efficiently analyzed. In addition to isolating high voltage DC power for safer information, the system enables technicians to quickly ascertain the productivity levels, potential problems, solutions and exact locations relating to each specific photovoltaic module within a solar array.

### FIELD OF THE INVENTION

The present invention relates to a system for monitoring the performance of the photovoltaic (PV) modules in a solar array, comprising a voltage sensor and a relatively small programmable micro-controller that join with various communications elements such as wires and controller to ultimately create the opportunity for greater PV efficiency through common communication between solar panels.

### BACKGROUND OF THE INVENTION

Solar arrays are often among the top preferred alternative energy sources. The sun provides an unlimited source of energy and is not expected within the next billion years to suffer the more immediate dissipating levels of abundance as is foreseen with energy derived from fossil based fuels. In fact, solar arrays significantly relieve society of many of the social, political and financial burdens associated with more traditional sources of energy. However, current solar array technology is not perfect as deference to the solar technology grows exponentially.

The primary issue with solar arrays relates to the PV modules that serve to make up a solar array. PV modules typically experience individual detriments such as life span, poor connection, dirt buildup and individual degradation. When a PV module experiences such a detriment, the efficiency of the entire solar array may be affected. Because of this issue, the present invention solves the need for a system that combines all PV modules into a common communications network in order to monitor and verify the operation of individual PV modules.

Current techniques for monitoring the performance of individual PV modules often are akin to checking each individual light on a Christmas or holiday display to determine which faulty light is causing the entire decoration to fail in its performance. This is especially true when a technician is tasked with manually finding a failing panel. It can be very time consuming to find a failure among the tightly packed rows of PV modules as the technician would have to test individual voltage levels and move individual PV modules. In addition, this invasive approach often can lead to new problems. From this standpoint, the present invention solves the need for a system that contains an automatic, built-in process for monitoring the performance of each individual PV module.

Current attempts at monitoring the performance of each PV module require the user to run sense wiring from each panel down to some type of voltage monitoring system, where each PV module must be checked periodically. These current attempts require a large number of wires. That reality is highlighted by the fact that a typical commercial system (25 kw) consists of 144 PV modules. Moreover, these wires based on the current attempts also carry considerable risks due to the potentially high voltage (0-600 VDC). The present invention uniquely avoids this danger while also saving considerable amount of resources in terms of the number of wires. Instead, the system of the present invention is comprised of a voltage sensor and a small programmable micro-controller that utilizes a serial communications protocol to ultimately allow a relatively large number of PV modules to share common communication wires with the communications controller. Moreover, the danger element of current attempts to solve this problem is avoided because the present invention isolates its wires from the power generation system and consists of low voltage components.

The present invention is essential to the monitoring of PV modules because the system of the present invention offers continuous monitoring of a solar array's performance at the smallest field replaceable unit. This is a substantial improvement on existing systems that monitor the operation of sub-systems at the inverter level, because unlike those monitoring attempts, the present invention's monitoring of individual PV modules is much more effective in identifying even the most minute of issues such as dirt buildup and panel degradation.

U.S. Pat. No. 4,695,788 issued to Marshall on Sep. 22, 1987, is a method used to find faults in a string of series-connected systems relating to offline diagnosis of problems within the system. Unlike the present invention, Marshall does not monitor the performance of the individual PV modules over the operational life of the system.

U.S. Pat. No. 4,888,702 issued to Gerken on Dec. 19, 1989, is a method for monitoring the entire solar array performance. Unlike the present invention, Gerken monitors the system as a single unit. In contrast, the present invention monitors and examines the performance of each individual component of the solar array. In this manner, the present invention is much more apt to identify and pinpoint problems of an individual component such as a single PV module.

U.S. Pat. No. 6,107,998 issued to Kulik on Aug. 22, 2000, is a method used to evaluate a single panel through the use of a display on the panel to manually orient its position to provide a maximum output. Kulik does not adequately relate to solar arrays and is far from practical in terms of a blanket monitoring of individual components as is the case with the present invention.

U.S. Pat. No. 6,979,989 issued to Schripsema on Dec. 27, 2005, is a method used to estimate the maximum power a system can produce based upon a reference PV module and temperature sensor. Unlike the present invention, Schripsema cannot monitor individual component performance. The present invention, unlike Schripsema, also can collect data to determine when individual panel performance has degraded due to such factors as age.

WO/2007/006564 issued to Riese on Jan. 18, 2007, is a method used for detecting damage, theft, or some other catastrophic failure of PV modules, while also employing a central alarm device to its system. Unlike the present invention, Riese is not designed to monitor performance of individual components at the detailed and individually focused manner.

### SUMMARY OF THE PRESENT INVENTION

The present invention is a system that can monitor both the performance of individual PV modules and the performance of an entire solar array. The present invention employs a voltage level sensing circuit that feeds an analog to digital (A/D) converter. The A/D converter is powered from the PV module that is connected to a micro-controller. The micro-controller is isolated from the individual PV modules with optical isolators. This element of the present invention serves to keep the high voltage DC away from the sensing circuits. In an additional embodiment, the micro-controller is also connected to the communications controller via a communications interface, an example being RS-485, which is used to collect, relay or process data.

The data collected by the communications controller can be used to monitor present operation of the individual components of the solar array, as well as maintain historical logs and predict future power production. In addition, the communications controller will be used to perform a comparative analysis between all PV modules to seek out data indicating underperforming PV modules. This information could indicate such conditions as specific PV modules in need of surface-glass cleaning or possible replacement if defective. Meanwhile, the A/D converter also can monitor the current passing through the panel in order to monitor the power produced by the PV module as well as voltage.

The system of the present invention essentially provides sensors to identify the sufficiency, output, efficiency and most other relevant conditions of components of a solar array, particularly individual PV modules. In the manner employed by the system, the present invention affords users the ability to know exactly which PV module is underperforming. In the preferred embodiment of the present invention, two pairs of wires are connected to the voltage level sensing circuit in a manner that a sensor is effectively on each PV module, while at the same time, each voltage level sensing circuit is networked to a communications controller. The communications controller then runs using networking protocols back to a CPU. In an additional embodiment of the present invention, the system employs wireless transceivers, antenna, and a wireless master data concentrator in order to provide sensor monitoring of individual PV modules via wireless technology and as a another embodiment the information may be transmitted over the powerlines.

### BRIEF DESCRIPTION OF THE PREFERRED EMBODIMENT

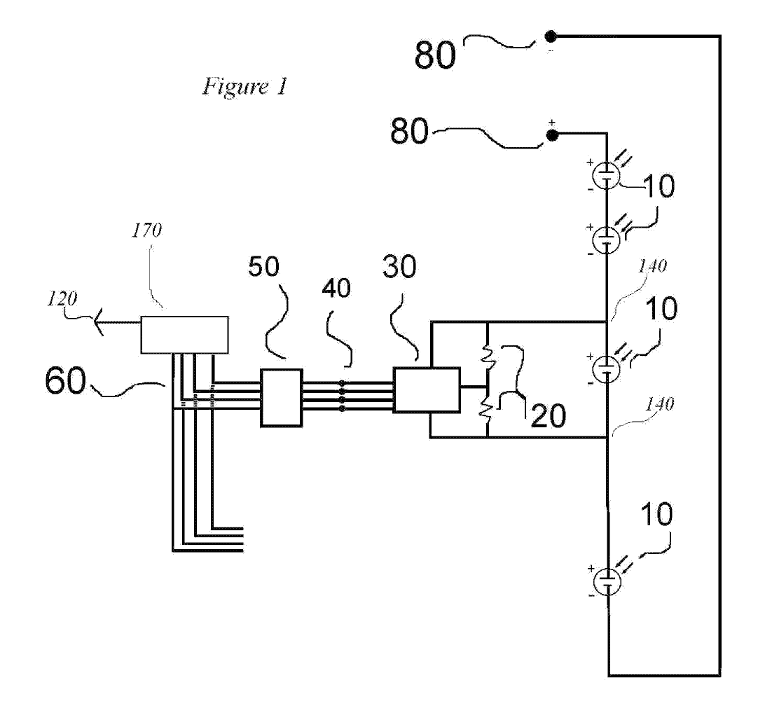

FIG. 1 is a schematic view of the present invention using a wired system

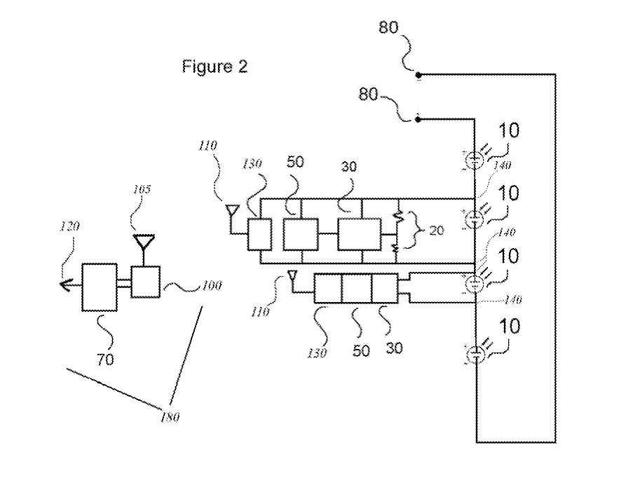

FIG. 2 is a schematic view of the present invention using a wireless system

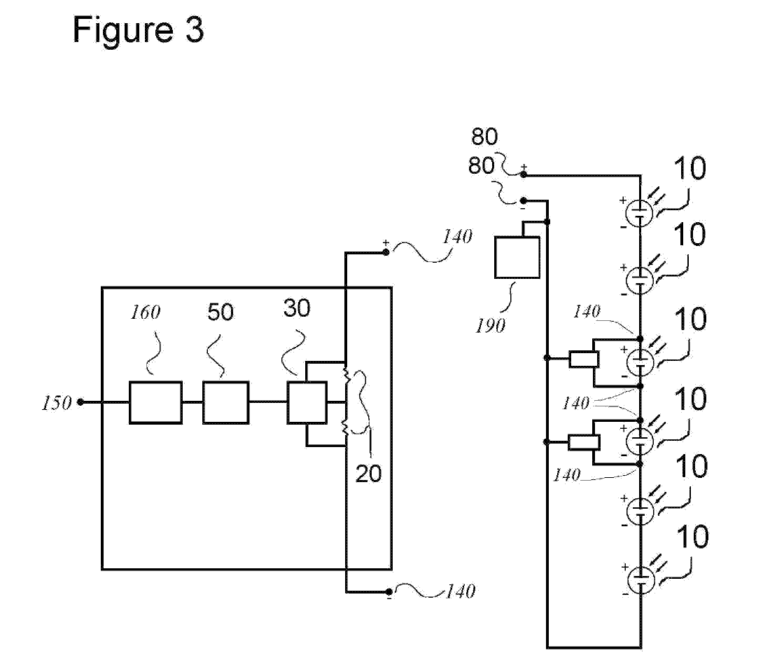

FIG. 3 is a schematic view of the present invention using a signaling over power system

### DETAILED DESCRIPTION OF THE PREFERRED EMBODIMENT

The system of the present invention uses sensing technology relating to individual PV modules (10) in order to detect fluctuations and relevant output levels of individual PV modules (10). FIG. 1 is a view of the present invention in its preferred embodiment. In this schematic view, we see how wired connections lead information directly from the individual PV modules (10) toward the system's sensing components of the overall solar array. The system receives power (140). A minimal amount of wires lead to the voltage level sensing circuit (20). The voltage level sensing circuit (20) receives voltage levels from the individual PV module (10) in its connection stream. In this manner, the voltage level sensing circuit (20) will detect the power output emanating from the individual PV module (10). For example, a dirty PV module (10) might emit a lower amount of power output than other fully functioning PV modules (10) in the solar array. This information, no matter how slight, would be detected by the voltage level sensing circuit (20) that is assigned to that particular PV module (10).

The voltage level sensing circuit (20) of FIG. 1 then feeds the information to an analog to digital (A/D) converter (30). The A/D converter (30) is powered from the PV module (10) as the information moves through optical isolators (40) and ultimately to a micro-controller (50). The optical isolators (40) isolate the high voltage DC power from the network, also known as a communications backplane. In other words, the optical isolators (40) serve to keep the high voltage DC away from the communication circuits.

From this point, FIG. 1 demonstrates that the information travels through the wires to a communications interface (60) and up toward a master data concentrator (170) which aids in the sensor monitoring aspect of the present invention. In the preferred embodiment of FIG. 1, we see that the information then is transferred to a standard communications interface (120). The standard communications interface (120) links the system of the present invention to a computing device. Appropriate software capable of analyzing the data gleaned from the system of the present invention would then assist the user in organizing the data and alerting the user of any issues pertaining to individual PV modules (10). This information that is articulated by the software would allow the user to determine possible causes of the different output levels of a PV module (10) ranging from mundane elements such as dirt to complete failure and theft. The user also would be able to ascertain the exact location of the particular PV module (10) in question, regardless of the size and scope of the solar array.

FIG. 2 demonstrates an additional embodiment of the present invention in terms of a wireless system. As we see in FIG. 2, the wireless aspect maintains similar organization and design as the embodiment seen in FIG. 1. However, the wireless embodiment of FIG. 2 relates to the fact that instead of a completely wired data movement from the PV modules (10) to the standard communications interface (120) as is the case with the embodiment of FIG. 1, we see that this additional embodiment of FIG. 2 employs two antennas (110) to pass information.

In FIG. 2, we see the system of the present invention again relates to individual PV modules (10). Wires or comparable power output carriers pass the output levels from the individual PV modules (10) to the assigned voltage level sensing circuits (20) within the connection stream. However, after the information moves through the micro-controller (50), the information is guided into a wireless transceiver (130). The wireless transceiver (130) uses conventional means to transmit the information via an antenna (110) to the wireless master data concentrator (180). A receiving antenna (105), which is part of the wireless master data concentrator (180) located at a physically distant location, takes the information and passes the information through a receiving wireless transceiver (1 00). The information is then vetted through the communications controller (70) and ultimately is transferred to the standard communications interface (120) where the information is used via software and computing device in the same manner as described win FIG. 1. The communications controller assists this process by using networking protocols back to a CPU.

FIG. 3 is an additional embodiment of the present invention that uses wires gathering voltage information from the individual PV modules (10) and transfers the power levels through a power line master data concentrator (190). At a receiving point, power input (140) and sensing wires for data (150) with the said power input (140) providing power for this additional embodiment aspect of the present system. At this receiving point, the voltage level sensing circuit (20) performs its function relating to each individual PV module. From there, the data is transferred through the A/D controller (30) and then the micro-controller (50) in the same manner as in the previous embodiments. The signaling device (160) allows communications with the power line master data controller (190).

It is conceived that the data passed over the power line master data controller (190), the master data concentrator (170) or the wireless master data concentrator (180) must go to a location some distance away and be accessible for use in some way. In its preferred embodiment, a Module Monitoring System (MMS) would be a software package that could be run on a computer. The MMS will evaluate the performance of each PV Module on an ongoing basis. The most critical parameter in this evaluation is an estimation of the current light levels (BRIGHTNESS) that are available to the system. No current software package focuses on the brightness level as the data to show such a level was up that until this point is not available. There are a number of factors that affect the lighting level. This includes such items as time of day, season and weather as well as other data points. All such data points must be analyzed in order to be able to establish the true BRIGHTNESS level and when there is a problem with a particular PV module (10).

In a large array of PV modules (10), we can take an average of all the PV modules (10) to determine BRIGHTNESS since it is very unlikely that a failure would occur to a majority of the PV modules (10) at the same time. The numbers can be validated by examining the distribution of the readings against historical readings.

In smaller arrays (even single module systems), other methods need to be used. One additional embodiment is to install a reference PV module (10) that can be routinely tested to calibrate the BRIGHTNESS calculation. Another possibility is to rely upon a regional monitoring center that can monitor collections of small arrays and treat them as a larger array. This will give an independent sampling of the light levels that can be used to evaluate these systems. This regional monitoring center could also use radar maps or other weather telemetry to evaluate possible cloud cover or other small weather systems.

Once we have BRIGHTNESS determined, the performance of each PV module (10) can be evaluated. For each manufacturer's PV module (10), there will be published specifications on power output as a function of light levels and temperature, which the MMS can use as a baseline to evaluate performance of each PV module (10). Over time the MMS will collect data to modify these tables on a module-by-module basis. If the MMS is configured with the Model Number and Lot Number of each installed PV module (10) it may be possible to detect manufacturing issues tied to a specific batch of PV modules (10) by Lot number).

It is recommended in this embodiment that the readings should be taken a few times a day and there should be some allowable grace period when a PV module (10) is under performing because lower output could be from shadows from birds or workers on the roof, etc. When regional monitoring is performed, the grace period also will take into account for localized weather differences such as local clouds, scattered showers, etc.

The MMS will analyze the output of each PV module (10) and compare it to the BRIGHTNESS relative to the manufacturer's specifications; its performance relative to overall system output and other historical data and alarms will be signaled when a long term under performance situation is detected.

Although the MMS is the preferred method, other methods to analyze the data are available. For instance, multiple oscilloscope readings could be taken and graphed over time, which would allow for the BRIGHTNESS level to be obtained. One could even imagine modifying the data into sound levels where an unusual level would eventually be understood to mean that something is not correct by the human operator. Such methods are not nearly as efficient as MMS, however, they would work to some tangible degree.

We claim:

1. A monitoring system for photovoltaic modules, comprising:
at least one voltage level sensing circuit;
at least one analog to digital (A/D) controller;
optical isolators;
at least one micro-controller;
at least one communications interface; and
at least one master data concentrator.

2. The monitoring system for photovoltaic modules of claim 1, wherein energy conduits are configured to capture power output from the photovoltaic modules.

3. The monitoring system for photovoltaic modules of claim 2, wherein said energy conduits are connected to said at least one voltage level sensing circuit.

4. The monitoring system for photovoltaic modules of claim 3, wherein said at least one voltage level sensing circuit is configured to measure the power output of the photovoltaic modules.

5. The monitoring system for photovoltaic modules of claim 4, wherein said at least one analog to digital (A/D) controller is configured to transition the power output of the photovoltaic modules, that has been measured, from analog to digital information.

6. The monitoring system for photovoltaic modules of claim 1, wherein said optical isolators are configured to isolate high voltage DC power.

7. The monitoring system for photovoltaic modules of claim 1, wherein said at least one micro-controller is configured to adapt the power output of the photovoltaic modules, that has been measured, for processing.

8. The monitoring system for photovoltaic modules of claim 1, wherein said at least one communications interface is configured to transfer the power output of the photovoltaic modules, that has been measured, to said at least one master data concentrator.

9. The monitoring system for photovoltaic modules of claim 8, wherein said at least one master data concentrator is configured to assist in monitoring sensors.

10. The monitoring system for photovoltaic modules of claim 9, wherein a computing device and complementary software are configured to receive the power output of the photovoltaic modules, that has been measured.

11. A monitoring system for photovoltaic modules, comprising:
at least one voltage level sensing circuit;
at least one analog to digital (A/D) controller;
at least one micro-controller; and
at least two wireless transceivers.

12. The monitoring system for photovoltaic modules of claim 11, wherein a first of said at least two wireless transceivers is configured to transmit the power output of the photovoltaic modules, that has been measured.

13. The monitoring system for photovoltaic modules of claim 12, wherein a second of said at least two wireless transceivers is configured to receive the power output of the photovoltaic modules, that has been measured.

14. The monitoring system for photovoltaic modules of claim 13, wherein a computing device and complementary software are configured to receive the power output of the photovoltaic modules, that has been measured.

15. A monitoring system for photovoltaic modules, comprising:
at least one voltage level sensing circuit;
at least one analog to digital (A/D) controller;
at least one micro-controller; and
at least one power line master data concentrator.

16. The monitoring system for photovoltaic modules of claim 15, further comprising a signaling device configured to communicate with said at least one power line master data controller.
